(19) United States
(12) Patent Application Publication
(10) Pub. No.: US 2002/0192972 A1
(43) Pub. Date: Dec. 19, 2002

(54) Plasma processing

(76) Inventors: Masaki Narita, Yokohama-shi (JP); Katsuya Okumura, Tokyo (JP); Tokuhisa Ohiwa, Kawasaki-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/107,435

(22) Filed: Mar. 28, 2002

(30) Foreign Application Priority Data
Mar. 29, 2001 (JP) 2001-095307

(51) Int. Cl. H01L 21/302; H01L 21/461

(52) U.S. Cl. 438/710

(57) ABSTRACT

A plasma processing method comprises placing a substrate to be processed in a chamber having an inner wall, subjecting the substrate to plasma processing while the inner wall is set to a first temperature, and cleaning the inner wall by using plasma while the inner wall is set to a second temperature higher than the first temperature.

### CROSS-REFERENCE TO RELATED APPLICATIONS

This application is based upon and claims the benefit of priority from the prior Japanese Patent Application No. 2001-095307, filed Mar. 29, 2001, the entire contents of which are incorporated herein by reference.

### BACKGROUND OF THE INVENTION

1. Field of the Invention

The present invention relates to a plasma processing method in the semiconductor field, and more specifically, to a plasma processing method for cleaning an undesirable film formed on an inner wall of a vacuum processing chamber at the time a substrate is processed with plasma.

2. Description of the Related Art

As an apparatus for processing a semiconductor substrate with plasma, a Reactive Ion Etching (RIE) apparatus is known. In the RIE apparatus, while a negative potential is applied, a reactive gas (etching gas) is discharged using a high frequency power, thereby producing plasma, and ions in the plasma are impinged vertically on the surface of the wafer to etch physically and chemically the wafer.

When a viahole is formed in an insulating film, a gas containing fluorocarbon is used as an etching gas. More specifically, an etching gas having a good selectivity ratio is used to prevent a metal wiring layer exposed at the bottom of a viahole from being etched. Generally, a gas containing CHF₃ or C₄H₈ is employed.

When the RIE processing of the insulating film is carried out by using such an etching gas, the etching gas is decomposed within the plasma to produce fluorocarbon and carbon, which are deposited on the inner wall of a vacuum chamber. Also, part of a reaction product produced when the insulating film is processed by RIE is deposited on the inner wall of the vacuum chamber.

These fluorocarbon, carbon and reaction product are deposited on the inner wall of the vacuum chamber and gradually become thicker to form a film containing fluorocarbon (hereinafter referred to as a “deposited film”).

When the thickness of the deposited film reaches a predetermined thickness, it is peeled from the inner wall, thereby causing a problem of particles. At present, to prevent such a problem of particle generation in advance, the vacuum chamber is usually cleaned before the deposited film reaches the predetermined thickness. More specifically, while the vacuum chamber is opened and exposed to air, wet cleaning is performed.

There are various types of RIE processing of the insulating film. Therefore, gases to be selected are different according to the requirement. For example, in the RIE processing for forming a wiring groove in a damascene process, a gas is used which is different from the gas used in the RIE processing for providing be viahole.

The damascene process is a process that has recently come to be used. The damascene process is performed by forming a wiring groove by RIE in the surface of an insulating film, depositing a metal film over the entire surface so as to bury the wiring groove, and removing an undesired metal film outside the wiring groove by CMP (Chemical Mechanical Polishing).

In the case of the damascene process, the wiring groove has to be accurately patterned since the pattern of the wiring groove determines the pattern of the wiring layer. Therefore, unlike in the RIE processing for the viahole, a gas for producing a small amount of fluorocarbon and carbon when decomposed, is selected in the RIE processing for the wiring groove.

If gases to be selected are different, the deposited film formed on the inner wall of the vacuum chamber naturally differ in composition. When different RIE processing is carried out using a gas employed in the same vacuum chamber to deposit a stacked film composed of the deposited films each having greatly different composition, the stacked film would peel off for a short time under a thin condition of each deposited film according to difference in thermal expansion, thereby causing a problem of unwanted particles. Therefore, the peeling of the deposited film does not take place only by exceeding the predetermined thickness.

For avoiding the aforementioned problem, a processing object to be processed by the RIE apparatus is limited in consideration of the composition of the gas to be used and the quality of the deposited film.

Furthermore, when the composition of the gas used for every each step differs greatly, unwanted gas released from the deposited film formed in an immediately preceding step may affect the next process step. It is therefore necessary to prepare a number of RIE apparatuses more than the number of the process steps required for actual processing.

To overcome various problems mentioned above, the film deposited on the inner wall of the vacuum chamber is removed by plasma (plasma cleaning) after an RIE processing step is finished and before another RIE processing step is started. However, to remove the deposited film in this manner requires a long time. Hence, such a plasma cleaning is considered as an impractical method.

### SUMMARY OF THE INVENTION

According to an embodiment of the present invention, there is provided a plasma processing method which comprises:

placing a substrate to be processed in a chamber having an inner wall;

subjecting the substrate to plasma processing while the inner wall is set to a first temperature; and

cleaning the inner wall by using plasma while the inner wall is set to a second temperature higher than the first temperature.

According to another embodiment of the present invention, there is provided a plasma processing method which comprises:

placing a substrate to be subjected to plasma processing in a chamber;

introducing a gas into the chamber, to increase a pressure of the gas; and

exhausting the gas from the chamber to reduce a pressure of the gas in the chamber, thereby adiabatically cooling the chamber.

According to still another embodiment of the present invention, there is provided a plasma processing method which comprises:

placing a substrate to be processed in a chamber having an inner wall subjecting the substrate to plasma processing while setting the inner wall to a first temperature;

cleaning the inner wall while setting the temperature of the inner wall to a second temperature higher than the first temperature;

introducing a gas into the chamber to increase a pressure of the gas; and

exhausting the gas from the chamber to reduce a pressure of the gas, thereby adiabatically cooling the chamber.

### BRIEF DESCRIPTION OF THE DRAWINGS

FIG. 1 is a characteristic curve showing the relationship between CO emission intensity and cleaning time when the inner temperature of the vacuum chamber is at 60° C.;

FIG. 2 is a characteristic curve showing the relationship between CO emission intensity and cleaning time when the inner temperature of the vacuum chamber is at 110° C. and 150° C., respectively;

FIG. 3 is a characteristic curve showing the relationship between CO emission intensity and cleaning time when a gas previously heated is introduced into the vacuum chamber;

FIG. 4 is a schematic view of a plasma processing apparatus according to an embodiment of the present invention;

FIG. 5 is a sectional view of a substrate to be processed; and

FIG. 6 is a graph showing the difference in cleaning effect between the present invention and a prior art.

### EMBODIMENTS

Now, an embodiment of the present invention will be explained with reference to the accompanying drawings.

The inventors have accomplished the following experiments to efficiently remove a film deposited on the inner wall of the vacuum chamber with plasma.

In the first place, a silicon wafer was disposed on an electrode of a parallel plate RIE apparatus to deposit artificially a film on the inner wall of the vacuum chamber by applying plasma (first plasma processing) under the following deposition conditions:

| | |
|---|---|
| Pressure: | 100 mTorr, |
| High frequency to be | 1500 W and 13.56 MHz |
| applied to an electrode | |
| Supplied gas: | C₄F₈:CO:Ar:O₂ |
| | at flow rates of 15 SCCM:50 SCCM:200 SCCM: |
| | 5 SCCM, |
| Electrode temperature: | 40° C., |
| Inner wall temperature | 60°0 C. |
| of the vacuum | |
| chamber: | |
| Discharge time: | 2 hours |

O₂ gas was introduced into the vacuum chamber having the film deposited on the inner wall. The O₂ gas was discharged to produce plasma. The deposited film was tried to remove under the following removal conditions:

| | |
|---|---|
| Pressure: | 150 mTorr, |
| Power: | 2000 W, 13.56 MHz |
| Electrode temperature: | 40° C. |
| Inner wall temperature: | 60° C. |

The main component of the deposited film formed on the inner wall of the vacuum chamber was carbon (C). Therefore, the plasma cleaning process was stopped by checking disappearance of CO emission (Co intensity) through a quart window formed on the wall of the vacuum chamber. When the deposition film was removed in the aforementioned conditions, CO emission disappeared in about 12 minutes as shown in FIG. 1.

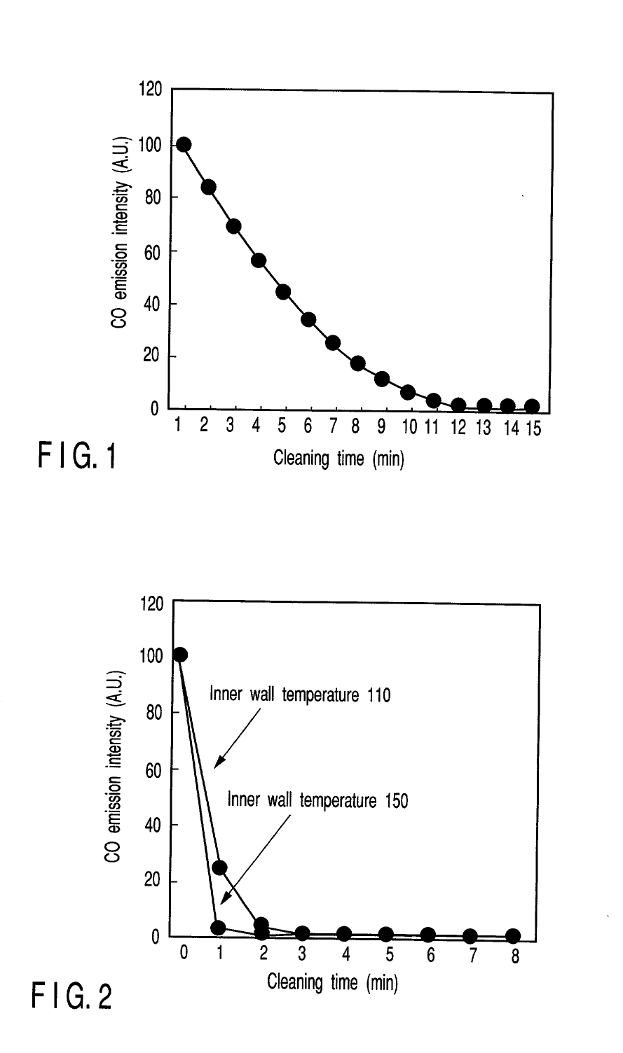

A deposition film formed under the same deposition conditions was removed under different removal conditions which were substantially the same as the aforementioned removal conditions except that the temperature of the inner wall was set at 110° C. In this case, CO emission intensity disappeared for a short time (about 2 minutes). In the case where the temperature of the inner wall was set at 150° C., the CO emission intensity disappears for a short time (about one minute) as shown in FIG. 2.

To introduce a previously heated gas (O₂ gas) into the vacuum chamber, a pipe connected to the vacuum chamber is heated and held at 150° C. Heated O₂ gas was introduced from the pipe of 150° C. into the vacuum chamber, and discharged to produce plasma. Thereafter, the deposited film was removed with the plasma under the following removal conditions:

| | |
|---|---|
| Pressure: | 150 mTorr |
| Power: | 2000 W, 13.56 MHz |
| Temperature of the electrode: | 40° C. |
| Inner wall temperature: | 60° C. |

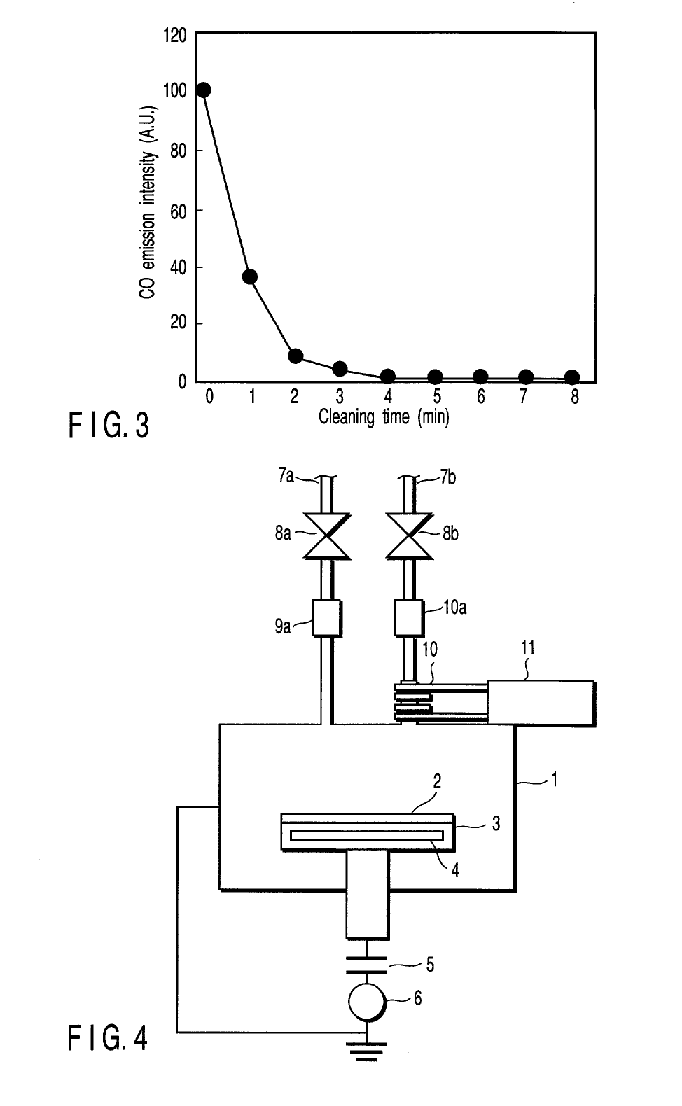

At this time, the temperature Of O₂ gas was about 120° C. at the inlet of the vacuum chamber. After the cleaning was performed for about 3 minutes, the Co emission intensity almost completely disappeared, as shown in FIG. 3. It is therefore found that the plasma cleaning capable of removing the deposited film for a short time can be attained.

To efficiently cool the vacuum chamber thus heated, adiabatic cooling was employed. More specifically, N₂ gas was introduced into the vacuum chamber up to 10 Torr. After the introduction of N₂ gas was stopped, an exhaust valve was opened to evacuate the N₂ gas. The pressure of the N₂ gas decreased to 4 mTorr after about 2 seconds, and the temperature of the inner wall of the vacuum chamber decreased by about 4° C.

As described above, by lowering the inner wall temperature for a short time, the transfer time from the plasma cleaning to a next plasma processing (second plasma processing) can be decreased, thereby improving the productivity.

In this case, the heater for heating the substrate in the vacuum chamber was off and a turbo molecular pump connected to the vacuum chamber was stopped in the evacuation. However, if the inner wall of the vacuum chamber was naturally cooled without the operation, it was required for 3 minutes to decrease the temperature of the chamber by 4° C.

Now, an embodiment will be explained more specifically.

FIG. 4 is a schematic view of a plasma processing apparatus. A vacuum chamber 1 includes an electrode 3 for disposing a substrate 2 to be processed thereon. The electrode 3 has a heater 4 for controlling the temperature of the substrate 2. The electrode 3 is connected to a high frequency power source 6 through a blocking capacitor 5. The vacuum chamber 1, which also serves as an opposite electrode, is grounded. A high frequency of 13.56 MHz is applied between the vacuum chamber 1 and the electrode 3 from the high frequency power source 6.

In addition, processing gases are supplied to the vacuum chamber 1 at a predetermined flow rate and pressure through gas supply lines 7a, 7b valves 8a, 8b and flow rate controllers 9a, 9b, respectively. As shown above, an RIE processing gas and a cleaning gas are separately supplied to the vacuum chamber 1.

A heater 10 for heating a cleaning gas for the deposited film was arranged around the gas supply line 7b. The heater 10 is connected to a power source 11. Furthermore, a heater is provided around the vacuum chamber 1 for heating the inner wall thereof.

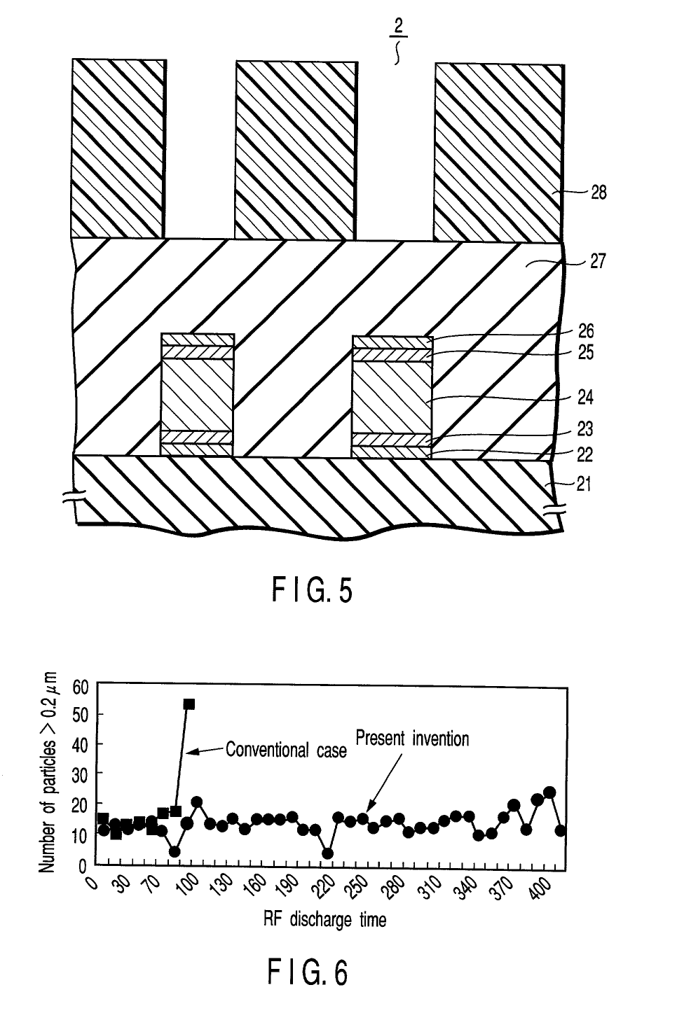

FIG. 5 shows a substrate 2 to be processed. The substrate 2 is formed as follows. In the first place, a silicon oxide film 21 is deposited to a thickness of 100 nm on a silicon substrate (not shown) by reduced-pressure CVD to form an interlayer insulating film. Thereafter, metal wiring layers (formed of a Ti film 22, TN film 23, Al film 24, TiN film 25, and Ti film 26) are formed and an interlayer insulating film 27 of 900 nm thick is deposited by reduced pressure CVD method to cover the entire surface of the metal wiring layers. Thereafter, CMP is carried out to planalize the uneven surface of the interlayer insulating film 27. Finally, a photoresist pattern 28 is formed on the interlayer insulating film 27 in order to form viaholes reaching the metal wiring layers.

Subsequently, the interlayer insulating film 27 is etched by using the photoresist pattern 28 as a mask in the plasma processing apparatus shown in FIG. 4. As a result, viaholes reaching the metal wiring layers are formed in the interlayer insulating film 27.

The etching is accomplished under the following etching conditions:

| | |
|---|---|
| Supplied gas: | C₄F₈:CO:Ar:O₂ at flow rates of |
| | 15 SCCM:50 SCCM:200 SCCM:5 SCCM |
| Pressure: | 45 mTorr, |
| Temperature of the substrate | 40° C., |
| 2: | |
| Power to be applied | 1500 W, 13.56 MHz |
| to the electrode 3: | |

Gases of C₄F₈:CO:Ar:O₂ are supplied through the gas supply lines 7a.

The O₂ gas previously heated by the heater 10 is introduced into the vacuum chamber 1 for processing for every 24 substrate 2. The O₂ gas thus introduced is discharged to produce the plasma, thereby removing the deposited film. The O₂ gas is introduced through the gas supply line 7b. Adiabatic compression may be used to heat O₂ gas. In this case, it is also preferable that the O₂ supply pipe is heated by the heater 10.

The cleaning conditions are as follows:

| | |
|---|---|
| Temperature of the substrate 2 | 120° C. |
| heated by the heater 4: | |
| Flow rate of O₂ gas | 1000 SCCM, |
| Pressure: | 150 mTorr |
| Power: | 2000 W, 13.56 MHz |
| Temperature of inner wall | 110° C. |
| of the vacuum chamber 1: | |

As CO emission intensity was monitored, 42 seconds was required until CO emission intensity disappeared. Cleaning was performed for 84 seconds, which was twice the disappearance time of CO emission intensity.

It took 90 seconds to increase the inner wall temperature of the vacuum chamber 1 from 60° C. to 110° C. After the inner wall of the vacuum chamber 1 was heated to 110° C. to remove deposited film, the vacuum chamber 1 was cooled to a general temperature of 60° C. for processing the substrate. In this case, after the deposited film was removed, the vacuum chamber 1 was once evacuated and then N₂ gas was introduced to increase a pressure up to 10 Torr. Thereafter, valves 8a and 8b were opened to exhaust the gas up to a pressure of 5 mTorr. About 15 seconds was required to increase the pressure to 10 Torr or more (P1) by introducing N₂ gas into the vacuum chamber 1. About 2 seconds was required to evacuate the chamber to a pressure of 5 mTorr (P2) (after the evacuation valve is opened). That is, P1 and P2 satisfies P1>100·P2 within 2 seconds.

The cooling process was repeated 7 times within about 2 minutes. As a result, the temperature of the inner wall of the vacuum chamber 1 decreases from 110° C. to 65° C. Various parts within the vacuum chamber 1 were more efficiently cooled by adiabatic cooling.

In this example, the cooling process was repeated 7 times. The conditions (P1, P2, exhaust time) of the cooling process may be changed appropriately to sufficiently cool the chamber in a single operation.

Such adiabatic cooling requires a high vacuum. Therefore, when the vacuum chamber 1 is equipped with a turbo molecular pump (not shown), it is preferable that the turbo molecular pump is stopped or a bypass line is provided in order to prevent a large amount of gas from momentarily being introduced into the turbo molecular pump.

Generally, when the substrates are processed subsequently for about 70 hours, the deposited film peels off to produce unwanted dust. In this case, if the plasma cleaning is performed in accordance with this embodiment, it is possible to prevent dust (particle size: above 0.2 μm) from being generated over 400 hours of RF discharge time (plasma processing time), as shown in FIG. 6.

Wet cleaning of the vacuum chamber is generally carried out for every 70 hours. Once the wet cleaning is accomplished while the chamber is being exposed to the air, the chamber is restored to normal conditions for about 7 hours. If the plasma cleaning of the present invention is used, the cleaning cycle of the chamber can takes 6 times longer. Simultaneously, the stop time of the chamber can be reduced to 42 hours.

Assuming that the plasma cleaning of the present invention is carried out for every 90 minutes, which is required for processing 24 substrates, the number of cleaning operations is given by

400 hours(24000 minutes)/90 minutes=266.66.

If a single cleaning operation takes 5 minutes, the total cleaning time is given by

5 minutes×266.66 times=133.33 minutes (about 22 hours)

As a result, according to the present invention, the time during which the plasma processing apparatus stops is half the time required by a conventional apparatus.

When a normal plasma processing is performed after plasma cleaning is completed, the temperature of the inner wall of the vacuum processing apparatus 1 must be reduced. The temperature of the inner wall is reduced by once increasing the inner pressure of the vacuum chamber 1 and abruptly reducing the pressure (called adiabatic cooling). However, the temperature may be reduced by a cooling water. The chamber 1 may be more efficiently cooled if liquid nitrogen is used as a refrigerant.

According to the embodiment, when the substrates are processed with the plasma, the temperature of the inner wall of the chamber is set to higher temperature, for example, 10° C. or more, than that of the plasma processing, thereby carrying out the plasma cleaning of the chamber. Therefore, the deposited film formed on the inner wall of the chamber can be removed for a shorter time than usual.

The embodiment of the present invention has been explained. However, the present invention will not be limited to the embodiment. The present invention is applied to plasma etching, in particular, RIE. However the present invention may be applied to other plasma processing such as plasma CVD.

What is claimed is:

1. A plasma processing method comprising:
placing a substrate to be processed in a chamber having an inner wall;
subjecting said substrate to plasma processing while said inner wall is set to a first temperature; and
cleaning said inner wall by using plasma while said inner wall is set to a second temperature higher than said first temperature.

2. The plasma processing method according to claim 1, wherein said second temperature is 110° C. or more.

3. The plasma processing method according to claim 1, wherein an O₂ gas is introduced into said chamber to clean said inner wall by plasma of said O₂ gas.

4. The plasma processing method according to claim 3, wherein said O₂ gas is heated and introduced into said chamber.

5. The plasma processing method according to claim 1, further comprising applying a second plasma processing to said substrate while said inner wall is set at a temperature lower than said second temperature.

6. The plasma processing method according to claim 5, wherein said second temperature is 110° C. or more.

7. The plasma processing method according to claim 4, wherein heating of said O₂ gas is carried out by adiabatic compression.

8. A plasma processing method comprising:
placing a substrate to be subjected to plasma processing in a chamber;
introducing a gas into said chamber to increase a pressure of said gas; and
exhausting said gas from said chamber to reduce a pressure of said gas in said chamber, thereby adiabatically cooling said chamber.

9. The plasma processing method according to claim 8, wherein said gas is N₂ gas.

10. The plasma processing method according to claim 8, wherein said gas is quickly exhausted to satisfy the following relationship within 2 seconds:
P1>100·P₂
where P1 is the pressure of said gas when it is introduced and P2 is the pressure of said gas when it is exhausted.

11. The plasma processing method according to claim 8, wherein said chamber is once completely vacuum-evacuated before said gas is introduced into said chamber.

12. The plasma processing method according to claim 8, wherein operations of introducing and exhausting said gas is repeated several times.

13. A plasma processing method comprising:
placing a substrate to be processed in a chamber having an inner wall;
subjecting said substrate to plasma processing while setting said inner wall to a first temperature;
cleaning said inner wall while setting the temperature of said inner wall to a second temperature higher than said first temperature;
introducing a gas into said chamber to increase a pressure of said gas; and
exhausting said gas from said chamber to reduce a pressure of said gas, thereby adiabatically cooling said chamber.

14. The plasma processing method according to claim 13, wherein said second temperature is 110° C. or more.

15. The plasma processing method according to claim 13, wherein O₂ gas is introduced into said chamber to clean said chamber with the O₂ gas plasma.

16. The plasma processing method according to claim 15, wherein said O₂ gas is heated and introduced into said chamber.

17. The plasma processing method according to claim 16, wherein heating of said O₂ gas is performed by adiabatic compression.

18. The plasma processing method according to claim 13, wherein said gas is N₂ gas.

19. The plasma processing method according to claim 13, wherein said gas is quickly exhausted to satisfy the following relationship within 2 seconds:
P1>100·P₂
where P1 is the pressure of said gas when it is introduced and P2 is the pressure of said gas when it is exhausted.

20. The plasma processing method according to claim 13, wherein said chamber is once completely vacuum-evacuated before said gas is introduced thereinto.
